(19) United States
(12) Patent Application Publication
(10) Pub. No.: US 2007/0170556 A1
(43) Pub. Date: Jul. 26, 2007

(54) Semiconductor device having flange structure

(75) Inventors: Hyun-Soo Chung, Hwaseong-si (KR); Dong-Hyeon Jang, Suwon-si (KR); In-Young Lee, Yongin-si (KR); Dong-Ho Lee, Seongnam-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/635,011

(22) Filed: Dec. 7, 2006

(30) Foreign Application Priority Data
Jan. 20, 2006 (KR) 10-2006-0006293

(51) Int. Cl. H01L 23/495

(52) U.S. Cl. 257/666

(57) ABSTRACT

A semiconductor device may include a semiconductor element. A layer of material may be provided on the semiconductor element which may have an opening through which a bond pad may be exposed. At least one flange structure may be provided on the first bond pad, the at least one flange structure made of at least two metal layers with different etch rates.

This U.S. non-provisional application claims the benefit of priority under 35 U.S.C. §119 from Korean Patent Application No. 10-2006-0006293, filed on Jan. 20, 2006, in the Korean Intellectual Property Office (KIPO), the disclosure of which is incorporated herein by reference.

### BACKGROUND

1. Field

Example non-limiting embodiments relate generally to a device having a pad to which a conductive bump is attached, for example, to a semiconductor device having a bond pad.

2. Description of the Related Art

Generally, electronic products have been developed with the goal of achieving a small size, a low weight and a high speed. Accordingly, the structure of semiconductor devices may be changed to meet such requirements. An example of such a structural change in a semiconductor chip may involve changing a method of connecting a semiconductor chip from an existing wire bonding method to a bonding method using a conductive bump. By way of example only, a conductive bump may be used in a wafer level package (WLP), a flip chip, or a printed circuit board (PCB).

A semiconductor device may be mounted in an electronic product using a conductive bump. However, the conductive bump may be easily separated from the bonded surface by temperature changes and external impacts. Thus, semiconductor device manufacturers have researched ways to improve conductive bump joint reliability.

FIG. 1 is a sectional view of a bump pad of a conventional semiconductor device.

Referring to FIG. 1, a wafer level package 10 may include a semiconductor chip 12 in which an integrated circuit may be formed. A bond pad 14 and a bond pad redistribution pattern 20 may connect the function of the integrated circuit to the outside. The bond pad 14 may be exposed by a passivation film 16 which may be a top protecting layer.

The semiconductor chip 12 may be planarized by a first interlayer insulating layer 18 where the bond pad 14 is exposed. The bond pad redistribution pattern 20 may be formed on the first interlayer insulating layer 18 and may be electrically connected with the bond pad 14. The bond pad redistribution pattern 20 may be covered by a second interlayer insulating layer 22, and a portion of the bond pad redistribution pattern 20 may be exposed to form a bond pad 24. A conductive bump 26 may be attached to the bond pad 24.

For example, the wafer level package 10 may be mounted onto an electronic product, such as a mobile phone, that may be vulnerable to external impacts or that may undergo great changes in temperature. Thus, the bonded surface of the conductive bump 26 and the bond pad 25 may be broken. This problem may shorten the life time of such an electronic product.

### SUMMARY

Example, non-limiting embodiments may provide a semiconductor device that may improve joint reliability.

In an example, non-limiting embodiment, a semiconductor device may include a semiconductor element. A layer of material may be provided on the semiconductor element and may have an opening through which a first bond pad may be exposed. At least one flange structure may be provided on the first bond pad, the at least one flange structure may be made of at least two metals layers with different etch rates

According to an example, non-limiting embodiment, the semiconductor element may be a semiconductor chip that may have a passivation layer that may expose a second bond pad. The layer of material may be a first interlayer insulating layer. A bond pad redistribution pattern may be interposed between the passivation layer and the first interlayer insulating layer, and may be connected to the second bond pad.

According to an example, non-limiting embodiment, the at least one flange structure may include a first flange structure on an edge portion of the first bond pad and a second flange structure on a middle portion of the first bond pad.

According to an example, non-limiting embodiment, the at least one flange structure may include a lower metal layer that may be provided on the bond pad redistribution pattern. An upper metal layer may be provided on the lower metal layer and may protrude beyond a side wall of the lower metal layer. The lower metal layer may have a higher etch rate relative to the upper metal layer.

According to an example, non-limiting embodiment, the thickness of the lower metal layer may be greater than that of the upper metal layer

According to an example, non-limiting embodiment, the semiconductor device may include a seed layer interposed between the bond pad redistribution pattern and the at least one flange structure.

According to an example, non-limiting embodiment, the semiconductor element may be a semiconductor chip having an integrated circuit. The layer of material may be a passivation layer that may be provided on the surface of the semiconductor chip.

According to an example, non-limiting embodiment, the semiconductor element may be an insulating substrate having a printed circuit pattern provided on the surface. The layer of material may be a resist provided on the surface of the insulating substrate.

According to an example, non-limiting embodiment, the at least one flange structure may be a locking structure.

### BRIEF DESCRIPTION OF THE DRAWINGS

Example, non-limiting embodiments will be described with reference to the attached drawings.

FIG. 1 is a cross-sectional view of a bond pad of a conventional semiconductor device.

FIG. 2 is a cross-sectional view of a bond pad of a semiconductor device according to an example, non-limiting embodiment.

FIGS. 3 to 5 are schematic views of a method that may be implemented to form the bond pad of a semiconductor device according to an example, non-limiting embodiment.

FIG. 6 is a cross-sectional view of a conductive bump of a semiconductor device according to an example, non-limiting embodiment.

FIG. 7 is a cross-sectional view of a bond pad of a flip chip according to an example, non-limiting embodiment.

FIG. 8 is a cross-sectional view of a bond pad of a printed circuit board according to an example, non-limiting embodiment.

FIG. 9 is a cross-sectional view of a bond pad of a wafer level package according to another example, non-limiting embodiment.

FIG. 10 is a cross-sectional view of a bond pad for another example, non-limiting embodiment.

The drawings are provided for illustrative purposes only and are not drawn to scale. The spatial relationships and relative sizing of the elements illustrated in the various embodiments may be reduced, expanded and/or rearranged to improve the clarity of the figure with respect to the corresponding description. The figures, therefore, should not be interpreted as accurately reflecting the relative sizing or positioning of the corresponding structural elements that could be encompassed by an actual device manufactured according to example embodiments of the invention. Like reference numerals in the drawings denote like elements, and thus their description may be omitted.

### DESCRIPTION OF EXAMPLE, NON-LIMITING EMBODIMENTS

Example, non-limiting embodiments will be described with reference to the accompanying drawings. The invention may, however, be embodied in many different forms and should not be construed as being limited to the embodiments set forth herein. Rather, the disclosed embodiments are provided so that this disclosure will be thorough and complete, and will fully convey the scope of the invention to those skilled in the art.

Well-known structures and processes are not described or illustrated in detail to avoid obscuring example embodiments.

An element is considered as being mounted (or provided) “on” another element when mounted or provided) either directly on the referenced element or mounted (or provided) on other elements overlaying the referenced element. Throughout this disclosure, spatial terms such as “upper,” “lower,” “above” and “below” (for example) are used for convenience in describing various elements or portions or regions of the elements as shown in the figures. These terms do not, however, require that the structure be maintained in any particular orientation.

FIG. 2 is a cross-sectional view of a bond pad of a semiconductor device 101A according to an example, non-limiting embodiment.

Referring to FIG. 2, a flange structure 110 may be provided on a pad 108 to which a conductive bump 120 may be attached. For example, a bond of the conductive bump 120 and the bond pad 118 may be weak at the bonding interface and the flange structure 110 may be provided to enhance the strength of the bonding interface. For example, the flange structure 110 may be a locking structure.

The flange structure 110 may include a lower metal layer 112. An upper metal layer 114 may be provided on the lower metal layer 112. The upper metal layer 114 may protrude beyond a side wall of the lower metal layer 112. For example, the upper metal layer 114 may be formed to retard the force (in the direction of arrows in the drawing) in the direction where the conductive bump 120 may separate from the attached surface. In this way, the flange structure 110 may absorb the impact, even if the impact is applied from the outside. Thus, reliability may be improved against an impact that may result when a semiconductor device is dropped, thereby general joint reliability may be improved.

Further, the area of the bonding interface of the conductive bump 120 and the bond pad 118 may be increased by as much as the surface area of the upper metal layer 114 that may protrude beyond the lower metal layer 112. In this way, the joint reliability may be improved.

The flange structure 110 may be applicable to various kinds of a pad to which a conductive bump may be attached. The shape or structure of the flange structure 110 may be altered by the retarding the force (in the direction of arrows in the drawing) in the direction where the conductive bump may separate from the attached surface.

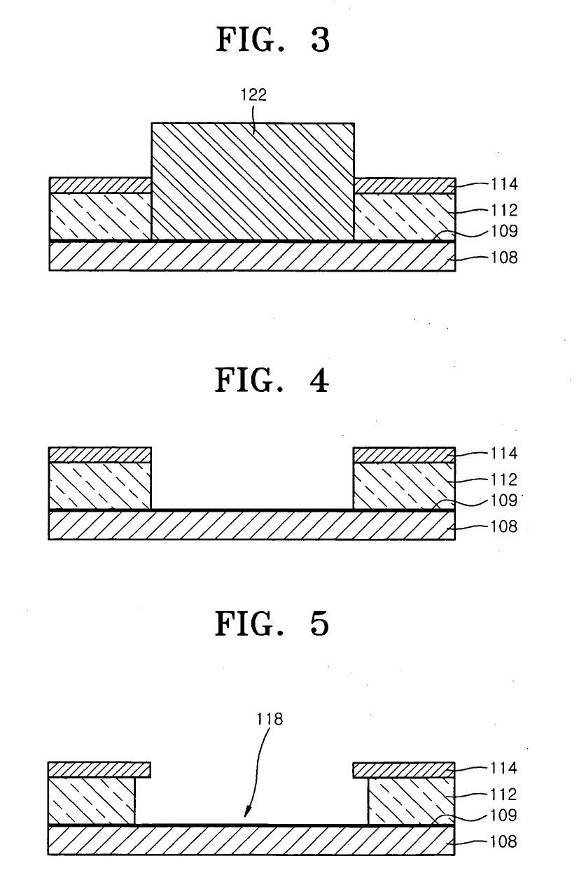

FIGS. 3 to 5 are sectional views of a method that may be implemented to form the bond pad of the semiconductor device according to an example, non-limiting embodiment.

Referring to FIGS. 3 to 5, a seed layer 109, which may perform the functions of an etching stopper and of a seed layer of a sputtering method, may be provided on a bond pad 118 of a pad 108, where a conductive bump may be provided. By way of example only, the seed layer 109 may be formed of one of titanium or chrome. A photoresist pattern 122 may be provided on the bond pad 118 where the seed layer 109 is formed. A lower metal layer 112 and an upper metal layer 114 may be sequentially stacked. By way of example only, the lower metal layer 112 may be formed by a sputtering method and a thickness thereof may be greater than that of the upper metal layer 114.

The material of the lower metal layer 112 may have a higher etch rate in isotropic wet etching than the material of the upper metal layer 114. The photoresist pattern 122 may be removed, and then, an isotropic wet etching may be performed on the resultant structure, in which the lower and the upper metal layers 112 and 114 may be formed. The lower metal layer 112 may be etched by the wet etching at the sides to be undercut. The upper metal layer 114, which may have a lower etch rate compared to that of the lower metal layer 112, may be etched less, so that the upper metal layer 114 may protrude beyond a side wall of the lower metal layer 112. By way of example only, copper may be used for the lower metal layer 112 and nickel may be used for the upper metal layer 114. A copper etchant then may be used as an etchant for the wet etching and a protruding structure may be formed. The seed layer 109 may also function as an etch preventive layer on the surface of the bond pad 118, thus the isotropic wet etching may not occur downward below the bond pad 118.

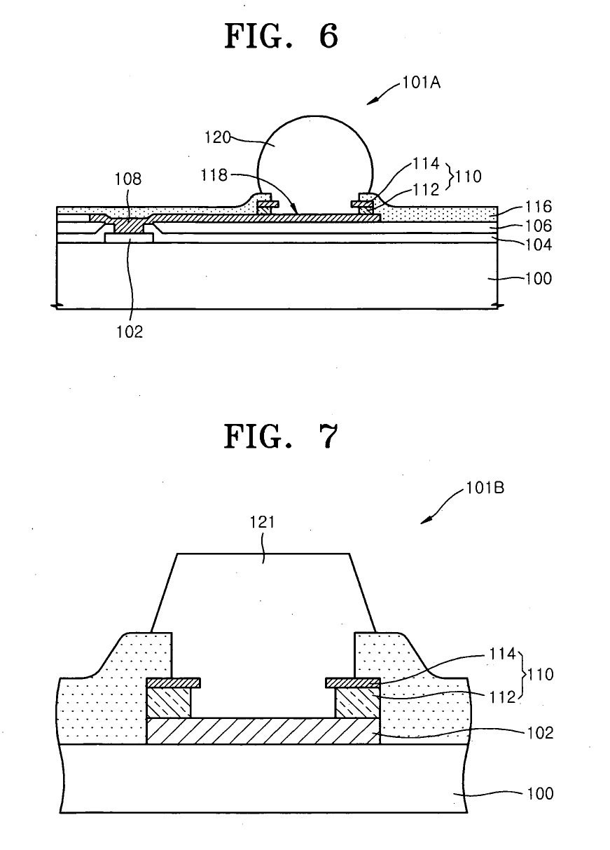

FIG. 6 is a cross-sectional view of a conductive bump of a semiconductor device according to an example, non-limiting embodiment.

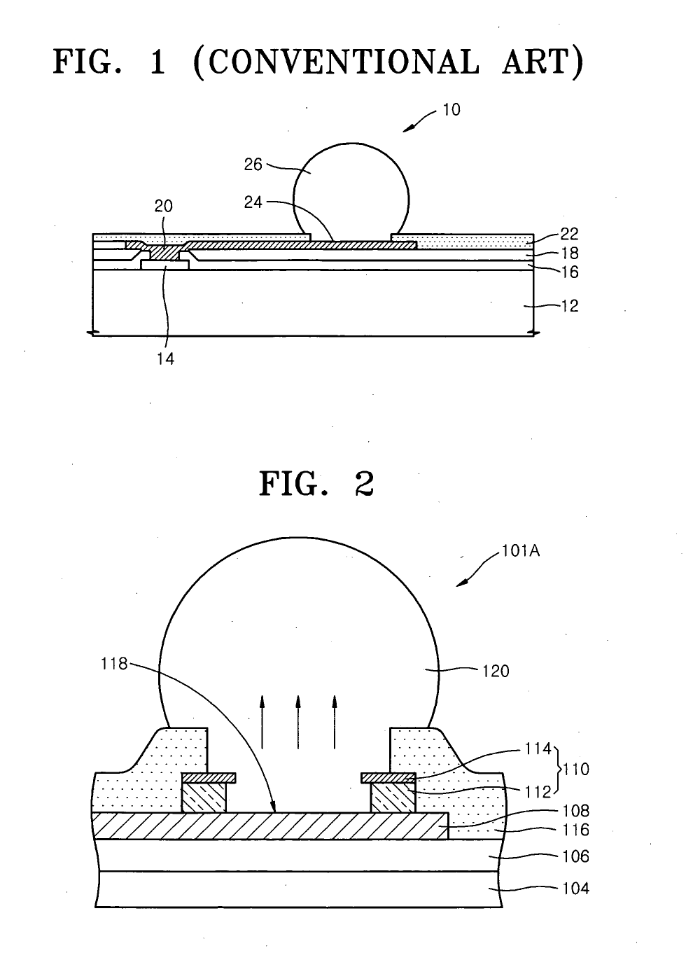

Referring to FIG. 6, a flange structure 110 may be applied to a wafer level package (WLP) 101A. In a general wafer level package 10 (FIG. 1), a bond pad may not have a flange structure. Thus, joint reliability may be weak and the conductive bump may be separated from the bond pad in the event that an electronic product is dropped or an external impact is occurs. However, in an example, non-limiting embodiment, the flange structure 110 may be positioned on the edge of a bond pad 118 and it may absorb the force when the conductive bump 120 separates. Thus, the joint reliability may be improved.

The semiconductor device may include a semiconductor chip 100. A passivation layer may be provided on the semiconductor chip 100 and may expose a first bond pad 102. A bond pad redistribution pattern 108 may be provided on the passivation layer 104 and may be connected to the first bond pad 102. A second interlayer insulating layer 116 may be provided on the bond pad redistribution pattern 108 and may form a second bond pad 118 by exposing a part of the bond pad redistribution pattern 108. A first flange structure 110 may be formed on an edge of the second bond pad 118 using metals with different etch rates.

A first interlayer insulating layer 106 for planarization may be interposed between the passivation layer 104 and the bond pad redistribution pattern 108.

By way of example only, the lower metal layer 112 of the first flange structure 110 may be nickel, and the upper metal layer 114 may be gold (Au). The materials of the lower and upper metal layers 112 and 114 may be replaced with other metals having different etch rates in isotropic wet etching.

FIG. 7 is a cross-sectional view of a bond pad of a flip chip according to an example, non-limiting embodiment.

Referring to FIG. 7, a flange structure may be applied to a flip chip 101B. A semiconductor device may include a semiconductor chip 100 that may have an integrated circuit. A bond pad 102 may be provided on the surface of the semiconductor chip 100. A passivation layer 104 may be provided on the surface of the semiconductor chip 100 and may expose the bond pad 102. A first flange structure 110 may be provided on the edge of the exposed bond pad 102 using metals with different etch rates. A conductive bump 121 may be provided on the bond pad 102 where the first flange structure 110 may be provided.

The first flange structure 110 may include a lower metal layer 112 provided on the bond pad 102. An upper metal layer 114 may be provided on the lower metal layer 112, and may protrude beyond a side wall of the lower metal layer 112. The upper metal layer 114 may have a lower etch rate relative to the lower metal layer 112. Further, the lower metal layer 112 may have a thickness greater than that of the upper metal layer 114, for example, which may improve solder joint reliability.

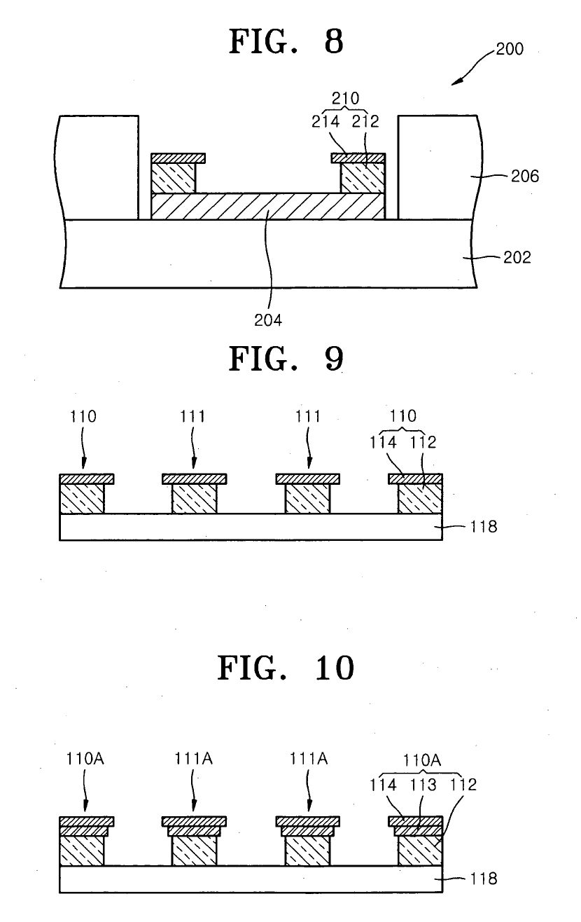

FIG. 8 is a cross-sectional view of a bond pad of a printed circuit board according to an example, non-limiting embodiment.

Referring to FIG. 8, the flange structure may be applicable to a bond pad of a printed circuit board (PCB) where a semiconductor device is mounted. The PCB may be a substrate used as a frame of a BGA package or may be a PCB for a memory module board.

A semiconductor device may include an insulating substrate 202 that may have a printed circuit pattern 204 provided on a surface. A resist 206 may be provided on the surface of the insulating substrate 202 and may expose a part of the printed circuit pattern 204. A bond pad 204 may be a part of the printed circuit pattern 204 that is exposed by the resist 206. A first flange structure 210 using metals with different etch rates may be provided on an edge of the bond pad 204.

By way of example only, the insulating substrate 202 may be formed of one of a polyimide material, FR4 resin and BT resin. The first flange structure 210 may include a lower metal layer 212 provided on the bond pad 204. An upper metal layer 214 may be provided on the lower metal layer 212, which may protrude beyond a sidewall of the lower metal layer 212. The upper metal layer 214 may have a lower etch rate relative to the lower metal layer 212. Also, the lower metal layer 212 may have a thickness greater than the thickness of the upper metal layer 214, for example, which may improve joint reliability.

FIG. 9 is a cross-sectional view of a bond pad of a wafer level package according to an example, non-limiting embodiment.

Referring to FIG. 9, a first flange structure 110 may be provided on an edge of a bond pad 118, and a second flange structure 111 may be additionally provided in a middle portion of the bond pad 118. The second flange structure 111 may be provided concurrently with the first flange structure 110, and a plurality of the first and second flange structures may be provided according to the size of the bond pad 118. For example, the second flange structure 111 may be applied to a wafer level package, but the second flange structure 111 may, for example, also be applied to a bond pad in a flip chip or a bond pad in a PCB in the same manner.

FIG. 10 is a cross-sectional view of a bond pad of an example, non-limiting embodiment.

For example, a flange structure may be formed by using the etch rate difference between two metals, e.g., the upper and lower metal layers. However, a flange structure may be formed with two or more metals, for example, three metals.

Referring to FIG. 10, the first and second flange structures 110A and 111A may include a lower metal layer 112 that may be provided on the bond pad. A middle metal layer 113 may be provided on the lower metal layer 112, and may protrude beyond a side wall of the lower metal layer 112. An upper metal layer 114 may be provided on the middle metal layer 113, and may protrude beyond a side wall of the middle metal layer 113. The lower metal layer 112 may have a highest etch rate, the middle metal layer 113 may have an intermediate etch rate, and the upper metal layer 114 may have a lowest etch rate, relative to each of the other layers. The flange structure may be altered in form if the flange structure absorbs the force (in the direction of arrows in FIG. 2) acting in the direction where the conductive bump separates from the bonded surface.

In accordance with example, non-limiting embodiments, the first and second flange structures that may be provided on the bond pad may increase the area to which the conductive bump may be attached. In this way, the conductive bump may be prevented from separating from the attached surface, thereby the joint reliability of a semiconductor device and/or a PCB may be improved.

Although example, non-limiting embodiments have been shown and described in detail herein, it should be understood by those of ordinary skill in the art that various changes in form and details may be suitably implemented without departing from the spirit and scope of the present invention as defined by the following claims.

What is claimed is:

1. A semiconductor device comprising:
a semiconductor element;
a layer of material provided on the semiconductor element having an opening through which a first bond pad is exposed; and
at least one flange structure provided on the first bond pad, the at least one flange structure made of at least two metal layers with different etch rates.

2. The semiconductor device of claim 1, wherein the semiconductor element is a semiconductor chip having a passivation layer exposing a second bond pad, wherein the layer of material is a first interlayer insulating layer, the semiconductor device further comprising a bond pad redistribution pattern interposed between the passivation layer and the first interlayer insulating layer and connected to the second bond pad.

3. The semiconductor device of claim 2, wherein the at least one flange structure includes a first flange structure on an edge of the first bond pad and a second flange structure on a middle portion of the first bond pad.

4. The semiconductor device of claim 2, wherein the at least one flange structure comprises:
a lower metal layer provided on the bond pad redistribution pattern; and
an upper metal layer provided on the lower metal layer, and protruding beyond a side wall of the lower metal layer,
wherein the lower metal layer has a higher etch rate relative to the upper metal layer.

5. The semiconductor device of claim 2, wherein the at least one flange structure comprises:
a lower metal layer formed on the bond pad redistribution pattern;
a middle metal layer provided on the lower metal layer and protruding beyond a side wall of the lower metal layer; and
an upper metal layer provided on the middle metal layer and protruding beyond a side wall of the middle metal layer,
wherein the lower metal layer has a highest etch rate, the middle metal layer has an intermediate etch rate, and the upper metal layer has a lowest etch rate, relative to each of the other layers.

6. The semiconductor device of claim 4, wherein the thickness of the lower metal layer is greater than that of the upper metal layer.

7. The semiconductor device of claim 2, further comprising a seed layer interposed between the bond pad redistribution pattern and the at least one flange structure.

8. The semiconductor device of claim 2, further comprising a second interlayer insulating layer interposed between the passivation layer and the bond pad redistribution pattern.

9. The semiconductor device of claim 7, wherein the seed layer is formed of one of titanium or chrome.

10. The semiconductor device of claim 4, wherein the lower metal layer is formed of nickel and the upper metal layer is formed of gold (Au).

11. The semiconductor device of claim 1, wherein the semiconductor element is a semiconductor chip having an integrated circuit and the layer of material is a passivation layer provided on the surface of the semiconductor chip.

12. The semiconductor device of claim 11, wherein the at least one flange structure includes a first flange structure on an edge of the first bond pad and a second flange structure on a middle portion of the first bond pad.

13. The semiconductor device of claim 11, wherein the at least one flange structure comprises:
a lower metal layer provided on the first bond pad; and
an upper metal layer provided on the lower metal layer, protruding beyond a side wall of the lower metal layer,
wherein the lower metal layer has a higher etch rate relative to the upper metal layer.

14. The semiconductor device of claim 11, wherein the at least one flange structure comprises:
a lower metal layer provided on the first bond pad;
a middle metal layer provided on the lower metal layer, protruding beyond a side wall of the lower metal layer; and
an upper metal layer provided on the middle metal layer, protruding beyond a side wall of the middle metal layer,
wherein the lower metal layer has a highest etch rate, the middle metal layer has an intermediate etch rate, and the upper metal layer has a lowest etch rate, relative to each of the other layers.

15. The semiconductor device of claim 13, wherein the thickness of the lower metal layer is greater than that of the upper metal layer.

16. The semiconductor device of claim 1, wherein the semiconductor element is an insulating substrate having a printed circuit pattern provided on a surface, and the layer of material is a resist provided on the surface of the insulating substrate.

17. The semiconductor device of claim 16, wherein the insulating substrate is formed from one of polyimide, FR4 resin and BT resin.

18. The semiconductor device of claim 16, wherein the at least one flange structure includes a first flange structure on an edge of the first bond pad and a second flange structure on a middle portion of the first bond pad.

19. The semiconductor device of claim 16, wherein the at least one flange structure comprises:
a lower metal layer provided on the printed circuit pattern; and
an upper metal layer provided on the lower metal layer, protruding beyond a side wall of the lower metal layer,
wherein the lower metal layer has a higher etch rate relative to the upper metal layer.

20. The semiconductor device of claim 17, wherein the at least one flange structure comprises:
a lower metal layer provided on the first bond pad;
a middle metal layer provided on the lower metal layer, and protruding beyond a side wall of the lower metal layer; and
an upper metal layer provided on the middle metal layer, and protruding beyond a side wall of the middle metal layer,
wherein the lower metal layer has a highest etch rate, the middle metal layer has an intermediate etch rate, and the upper metal layer has a lowest etch rate, relative to each of the other layers.

21. The semiconductor device of claim 19, wherein the thickness of the lower metal layer is greater than that of the upper metal layer.

22. The semiconductor device of claim 1, wherein the at least one flange structure is a locking structure.
